(19) United States
(12) Patent Application Publication
(10) Pub. No.: US 2007/0251820 A1
(43) Pub. Date: Nov. 1, 2007

(54) Sputtering target as well as a joined type sputtering target assembly and a method of making such a joined type sputtering target assembly

(75) Inventors: Junichi Nitta, Chiba-ken (JP); Takaharu Ito, Chiba-ken (JP); Hiroshi Matsumoto, Chiba-ken (JP); Manabu Ito, Chiba-ken (JP)

Correspondence Address: ARENT FOX PLLC, 1050 CONNECTICUT AVENUE, N.W., SUITE 400, WASHINGTON, DC, 20036, US

(73) Assignee: ULVAC Materials, Inc.

(21) Appl. No.: 11/783,260

(22) Filed: Apr. 6, 2007

(30) Foreign Application Priority Data
Apr. 28, 2006 (JP) 124829/2006

(51) Int. Cl. C23C 14/00

(52) U.S. Cl. 204/298.13

(57) ABSTRACT

[Object] It is to provide a sputtering target which has an excellent adhesion to films made of Au, Cu or an alloy containing at least one of Au and Cu and also an excellent corrosion resistance and which can be used to form an Mo—Ti alloy film over a large-sized substrate.

[SOLUTION] The present invention provides a sputtering target suitable for use in formation of an Mo—Ti alloy film on a substrate, characterized by that the sputtering target comprises Ti of higher than 50 atomic percentages but not exceeding 60 atomic percentages and the balance of Mo and inevitable impurities and that the relative density of the sputtering target is equal to or more than 98%. The present invention also provides a joined type sputtering target assembly formed by diffusion joining two of more of such sputtering targets, the length of the joined type sputtering target assembly being equal to or larger than 1,000 mm at least one side. The present invention further provides a method of making such a joined type sputtering target assembly.

A sputtering target as well as a joined type sputtering target assembly and a method of making such a joined type sputtering target assembly

### TECHNICAL FIELD

The present invention relates to a sputtering target as well as a joined type sputtering target assembly and a method of making such a joined type sputtering target assembly. In particular, the present invention relates to a sputtering target suitable for use in formation of a Mo—Ti alloy film as well as a joined type sputtering target assembly comprising such sputtering targets and a method of making such a joined type sputtering target assembly.

### BACKGROUND ART

In recent years, a thin-film transistor type liquid crystal display (TFT-LCD) has used, as an electric wiring film, a film made of any of lower resistivity metals such as Al, Cu, Ag and Au or an alloy containing at least one of said metals. Generally, such a film is inferior in any of heat resistance, corrosion resistance and adhesion which are required in the electric wiring film. This raises a problem in that the film cannot sufficiently satisfy the requirements in a process of forming electric wiring lines.

To solve the above problem, it was considered that a thin-film formed of a metal having a high melting point such as Cr, Mo and Ti was used as a base film on a substrate. In view of the heat resistance, corrosion resistance and adhesion, it has been found that an Mo alloy film and in particular an Mo—Ti alloy film is preferably used (e.g., see a patent document 1 attached here).

### [Patent Document 1]

Japanese Laid-Open Patent Publication No. 2005-29862 bulletin (in particular, see claim 1, paragraph [0012] and so on).

### SUMMARY OF THE INVENTION

### PROBLEMS TO BE SOLVED BY THE INVENTION

However, the above-mentioned Mo—Ti alloy film raises another problem in that it has an insufficient adhesion to a film made of a metal of Au or Cu or an alloy containing at least one of these metals, although the Mo—Ti alloy film has an excellent adhesion to a film made of Ag or Ag alloy.

In recent years, furthermore, a substrate on which a film is to be formed has increased in size. When a film is to be formed on such a large-sized substrate, several sputtering targets must be connected in parallel with one another to provide a large-sized sputtering target. In such a case, a certain abnormal electric discharge tends to occur at the connections to produce particles. Thus, there is a need for a joined type sputtering target assembly which is formed by joining sputtering targets together. However, the Mo—Ti sputtering target raises still another problem in that, in view of the characteristics of the materials used as well as the ability of an apparatus for making sputtering targets, it is difficult to make a joined type Mo—Ti sputtering target assembly from the Mo—Ti sputtering targets.

In view of the aforementioned problems, an object of the present invention is to provide a joined type sputtering target assembly which can be used to form an Mo—Ti alloy film which is superior in adhesion and corrosion resistance and to form such an Mo—Ti alloy film on a large-sized substrate.

### MEANS TO SOLVE THE PROBLEMS

Thus, the present invention provides a sputtering target suitable for use in formation of an Mo—Ti alloy film on a substrate, characterized by that said sputtering target comprises Ti of higher than 50 atomic percentages but not exceeding 60 atomic percentages and the balance of Mo and inevitable impurities, and that the relative density of the sputtering target is equal to or more than 98%.

If Ti is equal to or less than 50 atomic percentages, the adhesion of the formed Mo—Ti alloy film is insufficient. If Ti is higher than 60 atomic percentages, the corrosion resistance will be degraded. If the content of Ti is higher than 50 atomic percentages but not exceeds 60 atomic percentages, the resulting Mo—Ti alloy film will be excellent in adhesion and corrosion resistance. When the relative density of the sputtering target is equal to or higher than 98%, furthermore, the abnormal electric discharge causing particles to be produced can be restrained.

It is preferable that the oxygen concentration in the sputtering target is between 1,000 ppm and 3,500 ppm. If the oxygen concentration is less than 1,000 ppm, the joining step will cause any local oxidation which provides an uneven oxygen concentration at the joined part. As a result, the joining strength also becomes uneven. On the other hand, if the oxygen concentration is higher than 3,500 ppm, the joining strength will be degraded. When such a sputtering target is used to form the Mo—Ti alloy film, the resulting film will be degraded in resistance, stress and etching characteristics.

The present invention also provides a joined type sputtering target assembly formed by diffusion joining two or more of said sputtering targets, characterized by that the length of said joined type sputtering target assembly is equal to or more than 1,000 mm at least one side. When the joined type sputtering target assembly having its length equal to or more than 1,000 mm at least one side is used, an Mo—Ti alloy film can be formed on a large-sized substrate which has been used in recent production of TFT-LCD. Furthermore, the joining strength between the sputtering targets can be increased since the oxygen concentration thereof is higher. If this joined type sputtering target assembly is used to form an Mo—Ti alloy film, the abnormal electric discharge is less generated. And also, the resulting Mo—Ti alloy film will have an excellent adhesion to a film made of a metal such as Au or Cu or an alloy containing at least one of such metals with an increased corrosion resistance.

The present invention further provides a method of making a joined type sputtering target assembly, characterized by the steps of preparing sputtering targets by a powder sintering process or a melting process and diffusion joining the resulting sputtering targets at their end faces. When the sputtering targets are joined to one another in this manner, a large-sized joined type sputtering target assembly that would be difficult to be made in the prior art can be made easy and simply.

In the diffusion joining step, it is preferred that an Mo—Ti powder having its oxygen concentration between 1,000 ppm and 3,500 ppm is used as an insert material. This allows the production of a sputtering target having its higher joining strength.

### ADVANTAGES OF THE INVENTION

The sputtering target of the present invention is excellently advantageous to form an Mo—Ti alloy film which is superior in corrosion resistance and which has an excellent adhesion to a film made of a metal such as Au or Cu or an alloy containing at least one of Au and Cu. Furthermore, a joined type sputtering target assembly formed by the sputtering targets of the present invention has excellently advantageous in that the abnormal electric discharge can be restrained and that the assembly can be used to form an Mo—Ti alloy film on a large-scaled substrate. In addition, the method of a joined type sputtering target assembly according to the present invention is excellently advantageous in that the joined type sputtering target assembly can be made with an increased joining strength and in an easy and simple manner.

### BEST MODE FOR CARRYING OUT THE INVENTION

The sputtering target of the present invention contains Mo and Ti as chief ingredients and can be used to form a base film comprising a metal Au or Cu or an alloy containing at least one of Au and Cu.

In order to form a film which has an excellent adhesion to such a metal or alloy film and an excellent corrosion resistance, the sputtering target of the present invention should contain Ti of 50 or more atomic percentages but not exceeding 60 atomic percentages. In this case, it is desirable that the amount of any impurity contained in the sputtering target to improve and stabilize the characteristics of a metallic thin film provided by sputtering is reduced as little as possible. It is thus preferred that the combined purity of Ti and Mo except any gas component is equal to or higher than 99.9% by mass.

It is also preferable that the oxygen concentration of the sputtering target is between 1,000 ppm and 3,500 ppm. It is usually said that it is preferable that the oxygen concentration is as low as possible. When two or more sputtering targets are to be joined to one another to form a joined type sputtering target assembly which can support film formation to a large-sized substrate as described later, however, the lower oxygen concentration makes the oxygen concentration at the joining areas uneven. As a result, the joining strength will also be made uneven. Thus, the oxygen concentration is preferably between 1,000 ppm and 3,500 ppm and more preferably between 1,000 ppm and 2,000 ppm.

It is further preferable that the relative density of the sputtering target of the present invention is equal to or more than 98%. If the relative density of the sputtering target of the present invention is equal to or more than 98%, the abnormal electric discharge can be restrained to produce less particles.

If the sputtering targets of the present invention are simply connected in parallel with one another to form a large-sized sputtering target, the abnormal electric discharge tends to occur at the connecting areas. Thus, the joined type sputtering target assembly of the present invention is provided by diffusion joining 2 or more sputtering targets of the present invention at their end faces.

Since the length of the joined type sputtering target assembly of the present invention is equal to or more than 1,000 mm at least one side, an Mo—Ti alloy film can be formed even on a large-scaled substrate. By the way, the sputtering target and joined type sputtering target assembly according to the present invention may be rectangular or square.

A method of making a sputtering target and a joined type sputtering target assembly of the present invention will now be explained.

The sputtering target of the present invention can be provided through any suitable conventional technique such as a melting process or a powder sintering process.

The melting process includes an electron beam melting process, a plasma melting process and the like. In the electron beam melting process, the melting will be performed at a condition of ultimate vacuum equal to or lower than 5×10⁻³ Pa. In the plasma melting process, the melting will be executed under an atmosphere between 0.1 Pa and 0.5 Pa.

In the powder sintering process, a raw powdered material may be a mixed powder provided by mixing a simple power of Mo with another simple power of Ti at the predetermined rate described above. Furthermore, a powdered alloy produced with a predetermined composition through an atomization method or the like may be used. The oxygen concentration can be set at a predetermined rate by controlling the purity of an inert gas used on preparation of these raw materials and the condition of treatment.

The powder sintering process includes a hot press process in which a powder prepared with a predetermined composition is hot pressed within a carbon mold, HIP process in which a metal capsule that a powder is placed in is degassed and sealed then a hot isostatic pressing being performed, further CIP process in which a powder is pressure molded by a cold isostatic press as a pressurized molding then said molding being sintered. The Mo alloy suitable for forming the sputtering target of the present invention having the desirable composition is sinter formed at a heating temperature between 1,200 and 1,500 degrees Celsius and a pressure equal to or higher than 25 MPa in the hot pressing process; at a heating temperature between 900 and 1,200 degrees Celsius and at a pressure equal to or higher than 100 MPa in the HIP process; and at a heating temperature between 1,600 and 1,800 degrees Celsius after it has been pressurized at a pressure equal to or higher than 200 MPa in the CIP process. Thus, the sputtering target of the present invention having the relative density equal to or higher than 98% can be provided.

In the hot pressing process, the density will not be increased at a temperature less than 1,200 degrees Celsius since the pressure used is relatively lower. If the temperature exceeds 1,500 degrees Celsius, the Ti component will undesirably react to a carbon within the mold. In the HIP process, the sintering becomes insufficient if the temperature used is less than 900 degrees Celsius. If the temperature exceeds 1,200 degrees Celsius, the powder constituents may react to a capsule of mild steel or Fe alloy which is generally used as a container, resulting in melting the capsule. In the CIP process, any internal defect will be generated after sintering at a pressure equal to or lower than 200 MPa. This cannot provide a sufficient relative density.

According to the present invention, a joined type sputtering target assembly is made by joining two or more sputtering targets thus provided. In this case, it is preferable to use the HIP process or hot pressing process for diffusion joining the sputtering targets at their end faces. The HIP process is performed at a pressure of 100 MPa or higher and a heating temperature between 1,000 and 1200 degrees Celsius for a pressurizing time period between 2 and 6 hours. The hot pressing process is performed at a pressure of 25 MPa or higher and a heating temperature between 1300 and 1500 degrees Celsius for a pressurizing time period of 1-2 hours. The resulting sputtering target has a joining strength of 500 MPa or more. If the joined type sputtering target assembly has its joining strength equal to or more than 500 MPa, it can resist a stress generated in machining and bonding to a backing plate even if the length of the joined type sputtering target assembly is equal to or more than 1,000 mm at least one side.

Furthermore, if the joining (end) faces of the sputtering targets are diffusion joined to one another using a Mo—Ti powder having its oxygen concentration between 1,000 and 3,500 ppm (and preferably between 1,000 and 2000 ppm) as an insert material, the joining strength of the joined type sputtering target assembly becomes 800 MPa or more. The Mo—Ti powder may be a mixed power formed by mixing a simple power of Mo with another simple power of Ti at the predetermined rate. Furthermore, the Mo—Ti powder may be an alloy powder produced with a predetermined rate through atomization method or the like. The predetermined rate is the same as in the sputtering targets to be joined. The Mo—Ti powder may be placed on the joining faces with a width of about 10 mm (and particularly preferably a width of 5 mm-10 mm). Although the oxygen concentration of the Mo—Ti powder may be different from that of the sputtering target, it is not preferable that the difference of oxygen concentration exceeds 500 ppm since it may generate an uneven oxygen concentration at the joining areas.

### EXAMPLE 1

In this example, sputtering targets were prepared according to the present invention while changing the content of Ti therein and used to form Mo—Ti films on films of Au and Cu. Their adhesions to films of Au and Cu and corrosion resistances were estimated.

Mixed powders were prepared by mixing simple powers of Mo and Ti together such that they contain Ti of 2, 30, 50, 51, 55, 60, 62 atomic percentages, respectively. These mixed powders were used to prepare sputtering targets at a temperature of 1,350 degrees Celsius and a pressure of 250 MPa through the hot pressing process. The resulting sputtering targets were used to form Mo—Ti films (film thickness of 30 nm) on the respective films of Au and Cu under an atmosphere of Ar through the magnetron sputtering method.

Thereafter, the adhesions to the respective films were estimated by sticking and tearing off scotch tapes on the films. Furthermore, the corrosion resistances of the respective films were estimated by visually observing the surfaces thereof for discoloration after the films have been left for 12 hours under an environment of temperature of 50 degrees Celsius with humidity of 80%. The results of estimated adhesion and corrosion resistance are shown in Table 1. In the estimation of adhesion of Table 1, “Good” indicates no delamination; “Fair” indicates no delamination but defective; and “Failure” indicates the presence of delamination.

TABLE 1

| | Ti composition | Adhesion | | Face |
|---|---|---|---|---|
| Sample No. | (atomic percentages) | Au | Cu | Discoloration |
| 1 | 2 | Failure | Fair | Yes |
| 2 | 30 | Failure | Good | No |
| 3 | 50 | Fair | Good | No |
| 4 | 51 | Good | Good | No |
| 5 | 55 | Good | Good | No |
| 6 | 60 | Good | Good | No |
| 7 | 62 | Fair | Fair | Yes |

From Table 1, it is found that when the sputtering targets contain Ti of 50-62 atomic percentages, their adhesions to the Au film are good and also that such adhesions are particularly excellent if the Mo—Ti alloy films contain Ti of 51-60 atomic percentages. It is also found that the corrosion resistance in the sputtering targets is excellent since any discoloration is not observed when they contain Ti of 30-60 atomic percentages. It is understood from the above results that the sputtering targets of the present invention can be used to form Mo—Ti alloy films having their excellent adhesions and corrosion resistances particularly when the sputtering targets contain Ti of 51-60 atomic percentages.

### EXAMPLE 2

In this example, sputtering targets having different relative densities were formed while changing the condition of hot pressing. As the result, the number of abnormal electric discharges generated per unit hour was variable. Simple Mo and Ti powders were mixed together to provide a mixed powder containing Ti of 55 atomic percentages. This mixed powder was used to make sputtering targets having their relative densities of 90% (A), 94% (B), 95% (C), 97% (D), 98% (E) and 100% (F) in a hot press machine under sinter pressures of 15 MPa (A), 18 MPa (B), 20 MPa (C), 22 MPa (D), 24 MPa (E) and 25 MPa (F), respectively. These sputtering targets were used to form films for 120 minutes. The number of abnormal electric discharges generated during this film formation was counted. The results are shown in FIG. 1.

From FIG. 1, it is found that the number of generated abnormal electric discharges decreases as the relative density increases. More particularly, the number of generated abnormal electric discharges becomes minimum, three times in the relative density of 98% (E) while the number of generated abnormal electric discharges is 28 times in the relative density of 90% (A) and decreases to 15, 12 and 6 times in the relative densities 94% (B), 95% (C), 97% (D), respectively. It is thus found that when the relative density is 98% or more, the number of generated abnormal electric discharges drastically decreases to 5 times or less.

### EXAMPLE 3

In this example, sputtering targets having different oxygen concentrations were made while changing the atmosphere in which the mixed power was prepared. The resulting sputtering targets were tested with respect to their joining strength.

Simple Mo and Ti powders were mixed to provide a raw powder material containing Ti of 55 atomic percentages while changing the purity of an inert gas used in the mixing process. The resulting raw power was then used to make sputtering targets (30 mm×125 mm×12 mm) respectively having oxygen concentrations of 820 ppm, 1540 ppm, 3360 ppm and 3,780 ppm through the hot pressing process at a temperature of 1,350 degrees Celsius and a pressure of 25 MPa. These sputtering targets were diffusion joined together to provide joined type sputtering target assemblies (20 mm×200 mm×10 mm) in the HIP apparatus without any insert material under a condition in which a pressure is 100 MPa, a temperature is 1,000 degrees Celsius and a holding time is 4 hours. The resulting joined type sputtering target assemblies were tested with respect to the joining strength according to a bending strength testing method pursuant to JISR1601.

Furthermore, the aforementioned sputtering targets were diffusion joined together to make joined type sputtering target assemblies using the Mo—Ti mixed powder provided in the aforementioned manner as an insert material of 8 mm width on the joining faces. The resulting joined type sputtering target assemblies were tested with respect to the joining strength according to a bending strength testing method pursuant to JISR1601. The results are shown in Table 2.

TABLE 2

| | |
|---|---|
| Oxygen | |
| Concentration (ppm) | Joining |

| Sample No. | Target | Mo—Ti powder | Strength (MPa) |
|---|---|---|---|
| 1 | 820 | None | 359 |
| 2 | 820 | 740 | 483 |
| 3 | 1540 | None | 555 |
| 4 | 1540 | 1840 | 819 |
| 5 | 3360 | None | 532 |
| 6 | 3360 | 3190 | 806 |
| 7 | 3740 | None | 224 |
| 8 | 3740 | 3820 | 282 |

From Table 2, it is found that when the oxygen concentration is between 1,540 ppm and 3,360 ppm, the joining strength becomes equal to or higher than 500 MPa. It is also found that the joining strength becomes equal to or higher than 800 MPa when the joining faces are diffusion joined using the Mo—Ti powder as an insert material.

### EXAMPLE 4

In this example, joined type sputtering target assemblies having its length of 1,000 mm or more at one side were made and then tested with respect to the accumulated number of generated abnormal electric discharges.

Simple Mo and Ti powders were mixed to provide a mixed powder having the content of Ti equal to 55 atomic percentages. This mixed powder was used to make sputtering targets (750 mm×850 mm×10 mm) having the oxygen concentration of 1,230 ppm in the HIP apparatus under a sinter condition in which a temperature is 950 degrees Celsius, a pressure is 103 MPa and a pressurizing time is three hours. Furthermore, an Mo—Ti mixed powder having its oxygen concentration of 1,430 ppm was furthermore prepared under the same condition as described above. Two of the resulting sputtering targets were diffusion jointed to each other to provide a sputtering target assembly (1,450 mm×1,600 mm×8 mm) in the HIP apparatus under a condition in which a temperature is 1,050 degrees Celsius, a pressure is 103 MPa and a pressurizing time is 4 hours, with the above Mo—Ti mixed powder being used as an insert material on the joining faces of the sputtering targets. In addition, the accumulated number of generated abnormal electric discharges was counted during the formation of film for 15 hours under the same condition as in the example 1.

### COMPARATIVE EXAMPLE 1

Two sputtering targets (each 725 mm×800 mm×8 mm) were prepared under the same condition as in the example 4. The two sputtering targets were simply connected with each other to provide a large-sized (or split type) sputtering target assembly (1,450 mm×1,600 mm×8 mm). In addition, the accumulated number of generated abnormal electric discharges was counted during the formation of film for 15 hours under the same condition as in the example 4.

The results in the example 4 and comparative example 1 are shown in FIG. 2. From FIG. 2, it is found that the accumulated number of abnormal electric discharges increases when the sputtering time in the split type sputtering target assembly exceeds 5 hours. When the sputtering time is 15 hours, the number of abnormal electric discharges exceeds 60 times. On the contrary, the joined type sputtering target assembly prepared in the example 4 did not substantially cause the number of abnormal electric discharge to increase until 10 hours had elapsed. Even when the sputtering was continued for 15 hours, the number of generated abnormal electric discharge was only 18 times. It is thus found that the joined type sputtering target assembly according to the present invention can effectively reduce the number of abnormal electric discharges generated during the formation of film.

### INDUSTRIAL APPLICABILITY

The sputtering target of the present invention can be used to form an Mo—Ti alloy film having its excellent adhesion to the Au and Cu films and its excellent corrosion resistance. Furthermore, even a joined type sputtering target assembly using such sputtering targets will not substantially generate the abnormal electric discharge during the formation of film on the large-scaled substrate. Therefore, the present invention is extremely effective in the field of semiconductor production and particularly of TFT-LCD production.

### BRIEF DESCRIPTION OF THE DRAWINGS

FIG. 1 shows a graph showing the number of generated abnormal electric discharges when the relative density of the sputtering target is changed.

FIG. 2 shows a graph showing the accumulated number of generated abnormal electric discharge when the joined type sputtering target assemblies according to the present invention and the split type sputtering target assembly of the prior art are used to form films.

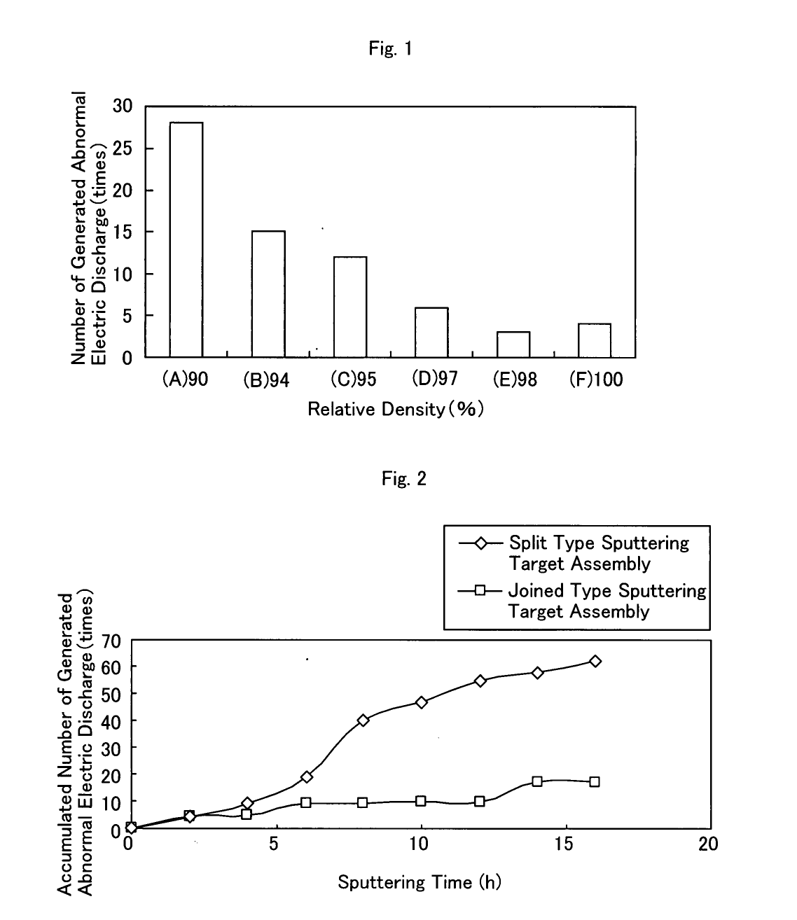

1. A sputtering target suitable for use in formation of an Mo—Ti alloy film on a substrate, characterized by that the sputtering target comprises Ti of higher than 50 atomic percentages but not exceeding 60 atomic percentages and the balance of Mo and inevitable impurities and that the relative density of the sputtering target is equal to or more than 98%.

2. The sputtering target according to claim 1, characterized by that the sputtering target has an oxygen concentration of 1,000-3,500 ppm.

3. A joined type sputtering target assembly comprising two or more diffusion-joined sputtering targets according to claim 2, characterized by that the length of said joined type sputtering target assembly is equal to or more than 1,000 mm at least one side.

4. A method of making a joined type sputtering target assembly, characterized by the steps of making sputtering targets according to claim 2 by a powder sintering process or a melting process and diffusion joining the resulting sputtering targets to one another at their end faces.

5. The method according to claim 4, characterized by that said diffusion joining step uses an Mo—Ti powder having its oxygen concentration of 1,000-3,500 ppm as an insert material.
